(19) United States
(12) Patent Application Publication
(10) Pub. No.: US 2024/0357762 A1
(43) Pub. Date: Oct. 24, 2024

(54) MODULAR DATA CENTER COMPUTER ROOM

(71) Applicant: Hebei Qinhuai Data Co., Limited., Zhangjiakou City (CN)

(72) Inventors: Binghua ZHANG, Zhangjiakou City (CN); Mingjiang LI, Zhangjiakou City (CN)

(21) Appl. No.: 18/635,871

(22) Filed: Apr. 15, 2024

(30) Foreign Application Priority Data
Apr. 21, 2023 (CN) 202310431969.3

(51) Int. Cl. H05K 7/14

(52) U.S. Cl. CPC H05K 7/1488; H05K 7/1497

(57) ABSTRACT

The present disclosure discloses a modular data center computer room, including a modular cabinet and a modular channel. The modular channel includes a frame body including a first frame and a second frame, where a preset distance is provided between the first frame and the second frame to form a hot channel. The first frame and the second frame both have a truss structure, and a certain spacing is provided between the truss structure and a bottom of the frame body to form a containment area. A plurality of the modular cabinets are provided and arranged side by side in the containment area, which is further internally provided with a positioning component, where an end of the positioning component comes into contact with the modular cabinet.

### CROSS REFERENCE TO RELATED APPLICATION

This application claims priority to Chinese Patent Application No. 202310431969.3, titled “MODULAR DATA CENTER COMPUTER ROOM” and filed to the China National Intellectual Property Administration on Apr. 21, 2023, the entire contents of which are incorporated herein by reference.

### TECHNICAL FIELD

The present disclosure relates to the technical field of data center computer room, and more particularly, to a modular data center computer room.

### BACKGROUND

In the era of rapid development of national informatization and digitization, data center computer rooms have become an important part of national economic development. With the scale expansion of data centers and the large-scale use of high-power density servers, heat production of a single cabinet has increased sharply. Therefore, it is required to plan internal airflow reasonably, thereby improving return air efficiency of air conditioners, and achieving effects of energy conservation and consumption reduction.

At present, most of the data center computer rooms are mainly equipped with sealed hot channels. However, the traditional sealed hot channels are complex in construction and cumbersome in installation, and thus cannot meet flexible deployment and elastic adaptation of the new generation of data center computer rooms.

### SUMMARY

Objectives of the present disclosure are to provide a modular data center computer room, which can, by arranging a positioning block to determine whether a modular cabinet moves into position, solve a technical problem that the modular cabinet cannot be accurately placed under a prefabricated hot channel structure in the existing technology. To achieve the above objectives, the present disclosure provides a modular data center computer room, which includes a modular cabinet and a modular channel. The modular channel includes a frame body including a first frame and a second frame, where a preset distance is provided between the first frame and the second frame to form a hot channel. The first frame and the second frame both have a truss structure, and certain spacing is provided between the truss structure and a bottom of the frame body to form a containment area. A plurality of the modular cabinets are provided and arranged side by side in the containment area, which is further internally provided with a positioning component, where an end of the positioning component comes into contact with the modular cabinet. When the modular cabinet moves along the containment area, the positioning component is driven to rotate until the positioning component is parallel to the truss structure.

As a further improvement of the above technical solutions, the frame body also includes at least four support rods positioned at four corners of the frame body, respectively. One end of each of the at least four support rods is connected to the truss structure, and other end of each of the at least four support rods is placed on ground.

As a further improvement of the above technical solutions, a bottom of each of the at least four support rods is detachably connected to a support leg, where a first bolt hole site is provided on the support leg.

As a further improvement of the above technical solutions, a bottom of the truss structure is provided with a plurality of second bolt hole sites configured to connect the at least four support rods.

As a further improvement of the above technical solutions, the positioning component is rotatably arranged on each of the at least four support rods, and a positioning slot is provided on the modular cabinet. When the modular cabinet moves into position, the positioning component is embedded into the positioning slot.

As a further improvement of the above technical solutions, a sensor is arranged on each of the at least four support rods, where a detection direction of the sensor faces toward the modular cabinet. When the positioning component is embedded into the positioning slot, a detection port of the sensor is positioned on an outer side of the modular cabinet.

As a further improvement of the above technical solutions, the truss structure at least includes two truss pieces, which are detachable connected to each other.

As a further improvement of the above technical solutions, a reinforcing rod is arranged on each of the two truss pieces to place a cable.

As a further improvement of the above technical solutions, the modular channel also includes baffles, a plurality of baffles are detachably connected to each of opposite sides of the two truss structures, and the plurality of baffles jointly constitute sidewalls of the hot channel.

As a further improvement of the above technical solutions, ends of the two truss structures are connected to form a channel door frame, and a baffle is arranged on the channel door frame, where the baffle covers the channel door frame.

As can be seen from the technical solutions provided by the present disclosure, hot air discharged from the modular cabinet is collected by means of the sealed hot channel, to prevent the hot air from mixing with cold air, and all the hot air is ensured to flow into an air-conditioning return air outlet for cooling. The cooled air is conveyed to an air inlet of the modular cabinet, avoiding rise of supply air temperature due to mixing of the cold air and the hot air inside the data center computer room, such that utilization rate of cooling capacity of an air conditioner is significantly improved, also more heat generated by devices is taken away, there achieving higher energy-saving effects. In this way, a power usage efficiency (PUE) value of the computer room is reduced, and it is ensured that operation and maintenance personnel work in a suitable temperature environment.

Furthermore, a positioning component is installed on the modular channel to accurately position the modular cabinet, thereby improving placement efficiency and accuracy of the modular cabinet.

### BRIEF DESCRIPTION OF THE DRAWINGS

To describe the technical solutions of the embodiments of the present disclosure more clearly, the accompanying drawings required in the description of the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic structural diagram of a prefabricated data center computer room according to an embodiment the present disclosure;

FIG. 2 is a schematic structural diagram of a prefabricated data center computer room according to an embodiment the present disclosure;

FIG. 3 is a schematic structural diagram of a positioning component according to an embodiment the present disclosure; and

FIG. 4 is a schematic structural diagram of a positioning component according to an embodiment the present disclosure.

Reference numerals in the attached drawings:
frame body 10; first frame 101; second frame 102; truss structure 103; support rod 104; support leg 105; reinforcing rod 106; baffle 107; modular cabinet 20; positioning slot 21; positioning component 30; and sensor 40.

### DETAILED DESCRIPTION

To make the objectives, technical solutions and advantages of the present disclosure clearer, the embodiments of the present disclosure will be further described in detail below with reference to the accompanying drawings. The terms such as “upper”, “above”, “lower”, “below”, “first end”, “second end”, “one end”, “other end” as used herein, which denote spatial relative positions, describe the relationship of one unit or feature relative to another unit or feature in the accompanying drawings for the purpose of illustration. The terms of the spatial relative positions may be intended to include different orientations of a device in use or operation other than the orientations shown in the accompanying drawings. For example, a unit that is described as “below” or “under” other units or features will be “above” the other units or features when the device in the accompanying drawings is turned upside down. Thus, the exemplary term “below” may encompass both the orientations of above and below. The device may be otherwise oriented (rotated by 90 degrees or facing other directions) and the space-related descriptors used herein are interpreted accordingly.

In addition, terms “installed”, “arranged”, “provided”, “connection”, “sliding connection”, “fixed”, and “sleeved” should be understood in a broad sense. For example, the “connection” may be a fixed connection, a detachable connection or integrated connection, a mechanical connection or an electrical connection, a direct connection or indirect connection by means of an intermediary, or internal communication between two apparatuses, elements, or constituent parts. The specific significations of the above terms in the present disclosure may be understood in the light of specific conditions by persons of ordinary skill in the art.

The present disclosure provides a modular data center computer room, which is described in detail below. It is to be noted that description order of the following embodiments does not limit preferred order of the embodiments of the present disclosure. In the foregoing embodiments, description of various embodiments may be focused on differentially, and reference may be made to related descriptions of other embodiments for a part not expatiated in a certain embodiment.

With the rapid development of information and communication industries, integration level and heat density of electronic devices are increasing. Sealed hot channels used in traditional data centers can no longer meet needs of contemporary data center computer rooms. At present, there are mainly two manners of installing the sealed hot channel of a data center. The first one is a fixed installation, that is, a bottom of the hot channel is fixed on a top of a modular cabinet. The hot channel cannot be installed unless the modular cabinet has been installed. In the first manner, construction period is longer, and the modular cabinet cannot be moved flexibly after the installation of the hot channel, making it difficult to meet flexible deployment and elastic adaptation of the new generation of data centers. The second one is a hanging installation, that is, the hot channel is installed by means of a floor slab in a hanging way. The second manner is complex and difficult in construction, and is demanding for technological requirements.

Therefore, most of the existing data center computer rooms use prefabricated hot channels to achieve physical isolation and directional flow of air inside the data center computer rooms, such that cooling capacity provided by precision air conditioners is fully utilized to improve return air efficiency of the air conditioner, thus achieving effects of energy conservation and consumption reduction.

However, the existing prefabricated hot channels are affected by their frame structures, which limits placement positions of the modular cabinets. Thus, it is not convenient for operation and maintenance personnel to operate when moving the modular cabinets, making it difficult to accurately locate the placement positions of the modular cabinets.

For this reason, embodiments of the present disclosure provide a modular data center computer room, which can, by arranging a positioning block to determine whether the modular cabinet moves into position, solve a technical problem that the modular cabinet cannot be accurately placed under the prefabricated hot channel structure in the existing technology. Detailed descriptions are made below, respectively.

The technical solutions in the embodiments of the present disclosure will be described clearly and completely below in conjunction with the accompanying drawings. Apparently, the embodiments described in the present disclosure are some but not all of the embodiments of the present disclosure. All other embodiments obtained by those skilled in the art based on the embodiments of the present disclosure without creative efforts shall fall within the protection scope of the present disclosure.

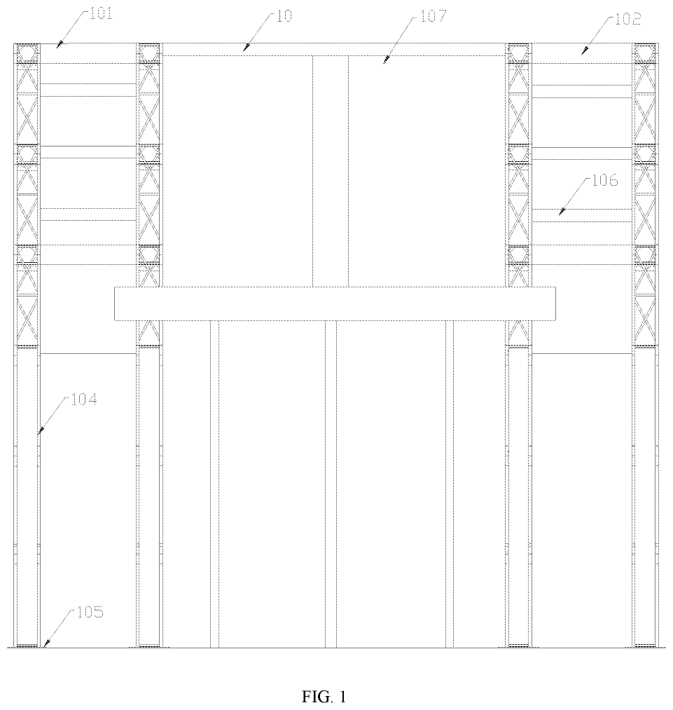

Referring to FIG. 1, a modular data center computer room includes a modular cabinet 20 and a modular channel. The modular channel includes a frame body 10, which includes a first frame 101 and a second frame 102, where a preset distance is provided between the first frame 101 and the second frame 102 to form a hot channel. The first frame 101 and the second frame 102 both have a truss structure 103, where certain spacing is provided between the truss structure 103 and a bottom of the frame body 10 to form a containment area. A plurality of the modular cabinets 20 are provided and arranged side by side in the containment area, which is further internally provided with a positioning component 30, where an end of the positioning component 30 comes into contact with the modular cabinet 20. When the modular cabinet 20 moves along the containment area, the positioning component 30 is driven to rotate until the positioning component 30 is parallel to the truss structure 103. In this way, placement accuracy of the modular cabinet 20 is improved by means of the positioning component 30, which can effectively avoid improper placement of the modular cabinet 20.

In an implementable embodiment, the frame body 10 also includes at least four support rods 104 positioned at four corners of the frame body 10, respectively. One end of each of the at least four support rods 104 is connected to the truss structure 103, and other end of each of the at least four support rods 104 is placed on ground. In practical applications, the support rods 104 are arranged in pairs, and there is a certain distance between two support rods 104 belonging to the same pair to expand a support range, thereby improving support stability of the truss structure 103.

In an implementable embodiment, a bottom of each of the at least four support rods 104 is detachably connected to a support leg 105, where a first bolt hole site is provided on the support leg 105. The support leg 105 can be connected to a bolt through the first bolt hole site and can be connected to the ground through the bolt to achieve fixation of the frame body 10. Specifically, the bolt can adopt a pre-embedded structure to improve fixation strength.

Further, a bottom of the truss structure 103 is provided with a plurality of second bolt hole sites configured to connect the at least four support rods 104. In this way, the truss structure 103 can be connected to the support rod 104 through the second bolt hole site. During the construction period, stability and safety of the frame body 10 is ensured during installation by increasing number of the support rods 104. In addition, the support rods 104 can be removed when the modular cabinet 20 is placed in the containment area to avoid adversely affecting the placement of the modular cabinet 20.

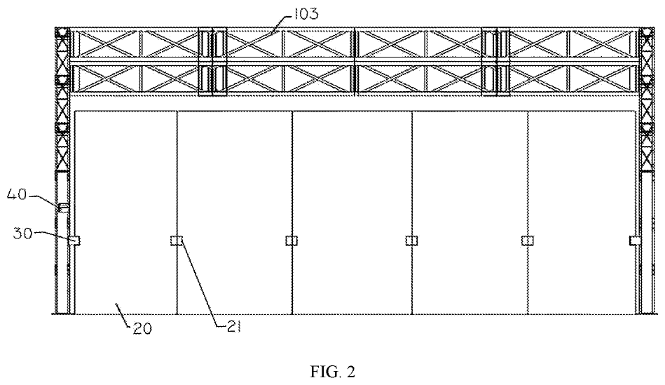

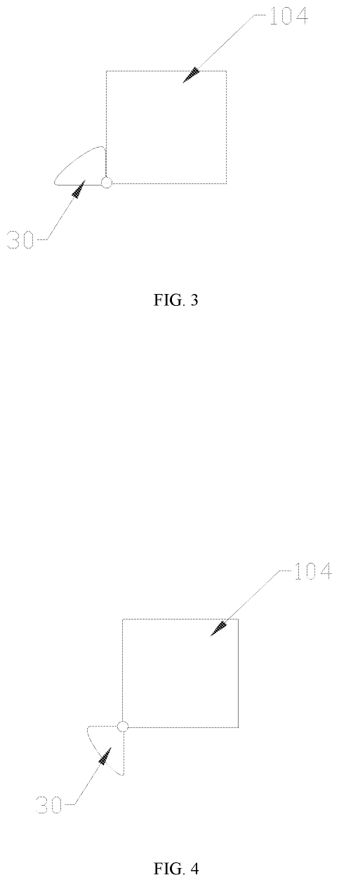

As shown in FIG. 2, in an implementable embodiment, the positioning component 30 is rotatably arranged on each of the at least four support rods 104, and a positioning slot 21 is provided on the modular cabinet 20, where the positioning slot 21 fits to the positioning component 30 both in shape and size. Specifically, the positioning component 30 is positioned on a side of the support rod 104 away from the hot channel. That is, when the modular cabinet 20 enters the containment area, a front end of a sidewall of the modular cabinet 20 first comes into contact with the positioning component 30, as shown in FIG. 3. Furthermore, the positioning component 30 is pushed to rotate until the modular cabinet 20 moves into position and gets away from the positioning component 30, causing a pushing force applied on the positioning component 30 to disappear and create a certain distance between the modular cabinet 20 and the positioning component 30, such that the positioning component 30 can rotate and can be embedded into the positioning slot 21. That is, the positioning component 30 uses its volume to compensate for the distance between itself and the modular cabinet 20, such that the positioning component 30 can limit the position of the modular cabinet 20, and it is ensured that the modular cabinet 20 has moved to a designated position. It is to be noted that when the operation and maintenance personnel move the modular cabinet 20 out of the hot channel, as shown in FIG. 4, they need to first rotate the positioning component 30 such that the positioning component 30 gets away from the modular cabinet 20, and then move the modular cabinet 20 such that the modular cabinet 20 comes into contact with the positioning component 30. By taking advantage of weight of the modular cabinet 20, it is ensured that the positioning component 30 does not appear on a moving path of the modular cabinet 20. In this way, the modular cabinet 20 can be moved out of the containment area.

Further, a sensor 40 is arranged on each of the at least four support rods 104, where a detection direction of the sensor 40 faces toward the modular cabinet 20. When the positioning component 30 is embedded into the positioning slot 21, a detection port of the sensor 40 is positioned on an outer side of the modular cabinet 20. In this way, it is detected whether rest of the modular cabinets 20 far away from the support rod 104 are placed in the designated position by means of the sensor 40. Furthermore, it is also determined whether the rest of modular cabinets 20 are placed in position according to a fact whether the rest of modular cabinets 20 are on a same horizontal line as the modular cabinet 20 near the support rod 104.

In an implementable embodiment, the truss structure 103 at least includes two truss pieces, which are detachable connected to each other. Specifically, the two truss pieces are stacked in a top-and-bottom structure to improve overall stability.

In an implementable embodiment, a reinforcing rod 106 is arranged on each of the two truss pieces to place a cable. Specifically, the reinforcing rod 106 is provided with at least three layers to place cables in multiple connection directions. Further, the reinforcing rod 106 may be detachable, facilitating adjustment of distances between a plurality of reinforcing rods 106, and changing number of the corresponding reinforcing rods 106 according to number of the cables. Still further, a hole is provided on the reinforcing rod 106 to fix cable organizers.

In an implementable embodiment, the modular channel also includes baffles 107, a plurality of baffles 107 are detachably connected to each of opposite sides of the two truss structures 103, and the plurality of baffles 107 jointly constitute sidewalls of the hot channel. Ends of the two truss structures 103 are connected to form a channel door frame, and the baffle 107 is arranged on the channel door frame, where the baffle 107 covers the channel door frame to constitute a channel door. In this way, the hot channel is sealed by arranging the channel door, which can effectively prevent accumulation of dusts inside the hot channel from adversely affecting use, thereby reducing frequency of cleaning and maintenance. Further, a door handle is arranged on the channel door, such that the operation and maintenance personnel can get in or out of the hot channel.

Because the hot channel is sealed, airflow inside the data center flows out from a rear side of the cabinet and then wholly returns to a data center air conditioning room through a return air outlet above the hot channel. In this way, it is avoidable mixing of cold air and hot air, which cannot flow back to a cold channel, thus improving refrigeration efficiency of the data center.

In an implementable embodiment, a plurality of channel adjusting plates are installed inside the hot channel to separate the plurality of modular cabinets 20, avoiding friction damage and poor heat dissipation effects caused by closer distance between the modular cabinets 20. By adjusting positions of the channel adjusting plates, the distance between two channel adjusting plates or between the channel adjusting plate and the channel door can be changed. Thus, positions of the channel adjusting plates can be changed according to sizes of the modular cabinets 20, making it easier to store and install the modular cabinets of different volumes, and also facilitating subsequent transformation and reconstruction of the modular channel.

To further increase speed and efficiency of air flow, an air-exhausting apparatus may be arranged on the rear side of the modular cabinet 20 or on the truss structure 103 to accelerate flow of the hot air into the hot channel, thereby improving heat dissipation efficiency. The air-exhausting apparatus may be an exhaust fan or air extractor, etc.

It is to be noted that both the frame body 10 and the reinforcing rod 106 are prefabricated in a factory according to requirements. After the prefabrication, the modular channel is transported to the site for rapid deployment. In the site, it is only required to connect the support leg 105 to the ground, and other parts are lifted and put into use, thereby improving construction efficiency of the computer room, saving construction cycles and design costs. Furthermore, adverse effects caused by future transformation of the data center are taken into full consideration to facilitate expansion and renovation.

As can be seen from the technical solutions provided by the present disclosure, the hot air discharged from the modular cabinet 20 is collected by means of the sealed hot channel, to prevent the hot air from mixing with the cold air, and all the hot air is ensured to flow into the air-conditioning return air outlet for cooling. The cooled air is conveyed to an air inlet of the modular cabinet 20, avoiding rise of supply air temperature due to mixing of the cold air and the hot air inside the data center computer room, such that utilization rate of cooling capacity of the air conditioner is significantly improved, also more heat generated by devices is taken away, there achieving higher energy-saving effects. In this way, a power usage efficiency (PUE) value of the computer room is reduced, and it is ensured that the operation and maintenance personnel work in a suitable temperature environment.

Furthermore, the positioning component 30 is installed on the modular channel to accurately position the modular cabinet 20, thereby improving placement efficiency and accuracy of the modular cabinet 20.

The embodiments set forth above are only illustrated as preferred embodiments of the present disclosure, and are not intended to limit the present disclosure. All modifications, equivalent substitutions and improvements made within the spirit and principles of the present disclosure shall fall within the protection scope of the present disclosure.

What is claimed is:

1. A modular data center computer room, comprising a modular cabinet and a modular channel; wherein
the modular channel comprises a frame body comprising a first frame and a second frame, a preset distance being provided between the first frame and the second frame to form a hot channel;
the first frame and the second frame both have a truss structure, a certain spacing being provided between the truss structure and a bottom of the frame body to form a containment area, a plurality of the modular cabinets being provided, and the plurality of modular cabinets being arranged side by side in the containment area; and
the containment area is further internally provided with a positioning component, an end of the positioning component coming into contact with the modular cabinet; and when the modular cabinet moves along the containment area, the positioning component is driven to rotate until the positioning component is parallel to the truss structure.

2. The modular data center computer room according to claim 1, wherein the frame body further comprises at least four support rods positioned at four corners of the frame body, respectively; and
one end of each of the at least four support rods is connected to the truss structure, and other end of each of the at least four support rods is placed on ground.

3. The modular data center computer room according to claim 2, wherein a bottom of each of the at least four support rods is detachably connected to a support leg; and
a first bolt hole site is provided on the support leg.

4. The modular data center computer room according to claim 3, wherein a bottom of the truss structure is provided with a plurality of second bolt hole sites configured to connect the at least four support rods.

5. The modular data center computer room according to claim 4, wherein the positioning component is rotatably arranged on each of the at least four support rods, and a positioning slot is provided on the modular cabinet; and
when the modular cabinet moves into position, the positioning component is embedded into the positioning slot.

6. The modular data center computer room according to claim 5, wherein a sensor is arranged on each of the at least four support rods, a detection direction of the sensor facing toward the modular cabinet; and when the positioning component is embedded into the positioning slot, a detection port of the sensor is positioned on an outer side of the modular cabinet.

7. The modular data center computer room according to claim 1, wherein the truss structure at least comprises two truss pieces, and the two truss pieces are detachable connected to each other.

8. The modular data center computer room according to claim 7, wherein a reinforcing rod is arranged on each of the two truss pieces to place a cable.

9. The modular data center computer room according to claim 1, wherein the modular channel further comprises baffles, a plurality of baffles are detachably connected to each of opposite sides of the two truss structures, and the plurality of baffles jointly constitute sidewalls of the hot channel.

10. The modular data center computer room according to claim 9, wherein ends of the two truss structures are connected to form a channel door frame; and
a baffle is arranged on the channel door frame, the baffle being configured to cover the channel door frame.
